(19) United States
(12) Patent Application Publication
(10) Pub. No.: US 2026/0344319 A1
(43) Pub. Date: Oct. 29, 2026

(54) SEMICONDUCTOR SUBSTRATE, ETCHING METHOD, AND METHOD FOR MANUFACTURING SEMICONDUCTOR COMPONENT

(71) Applicant: SEIKO EPSON CORPORATION, Tokyo (JP)

(72) Inventors: Masahiro FUJII, SHIOJIRI-SHI (JP); Kazuhiro USHIYAMA, OKAYA-SHI (JP); Yuta YUASA, SUWA-SHI (JP)

(73) Assignee: SEIKO EPSON CORPORATION, Tokyo (JP)

(21) Appl. No.: 19/655,666

(22) Filed: Apr. 22, 2026

(30) Foreign Application Priority Data
Apr. 24, 2025 (JP) 2025-072689

(51) Int. Cl. H10P 50/68; H10P 50/00

(52) U.S. Cl. CPC H10P 50/683; H10P 50/73

(57) ABSTRACT

A semiconductor substrate includes a first surface, a second surface opposite the first surface, and a diamond-like carbon film provided on at least the first surface of the substrate. An intensity of a D peak in a Raman spectrum of the diamond-like carbon film is defined as I(D), an intensity of a G peak in the Raman spectrum is defined as I(G), and a ratio of I(D)/I(G) satisfies I(D)/I(G)≤2.1.

The present application is based on, and claims priority from JP Application Serial Number 2025-072689, filed Apr. 24, 2025, the disclosure of which is hereby incorporated by reference herein in its entirety.

### BACKGROUND

### 1. Technical Field

The present disclosure relates to a semiconductor substrate, an etching method, and a method for manufacturing a semiconductor component.

### 2. Related Art

A method for etching a semiconductor surface using a noble metal as a catalyst is referred to as a noble metal-assisted chemical etching (Metal-Assisted Chemical Etching) method, and has attracted attention as a method capable of processing a semiconductor surface with high selectivity.

JP-A-2017-152710 discloses an etching method including bringing a semiconductor having a catalyst made of a noble metal formed thereon into contact with an etching solution containing hydrofluoric acid, an oxidizing agent, and an organic additive to remove a portion of the semiconductor in contact with the catalyst. According to such an etching method, a recess having a high aspect ratio can be formed.

JP-A-2012-169316 discloses a substrate with an etching mask in which a diamond-like carbon (DLC) pattern is formed on a surface of a substrate made of Si. The DLC pattern functions as an etching mask when a recess pattern is formed in the substrate by etching.

JP-A-2017-152710 and JP-A-2012-169316 are examples of the related art.

When the DLC pattern is used as an etching mask in the noble metal-assisted chemical etching method, the DLC pattern needs to reliably protect the surface of the substrate. However, when the adhesion between the substrate and the DLC pattern is low, an etching solution may enter the interface. As a result, etching proceeds in an unintended direction, and an etching defect occurs. As a result, the processing accuracy is reduced.

Therefore, there is a need to achieve a semiconductor substrate and an etching method capable of suppressing the occurrence of such an etching defect.

### SUMMARY

A semiconductor substrate according to an application example of the present disclosure includes:
a first surface;
a second surface opposite the first surface; and
a diamond-like carbon film provided on the first surface of the substrate,
wherein an intensity of a D peak in a Raman spectrum of the diamond-like carbon film is defined as I(D), and an intensity of a G peak in the Raman spectrum is defined as I(G), and
a ratio of I(D)/I(G) satisfies I(D)/I(G)≤2.1.

An etching method according to an application example of the present disclosure is a method for etching a semiconductor substrate according to an application example of the present disclosure, the method including:
forming a resist film on the diamond-like carbon film so as to have an opening in a first region of the substrate and cover a second region of the substrate;
etching the diamond-like carbon film corresponding to the opening;
forming a porous noble metal film on a surface of the substrate corresponding to the first region; and
etching the substrate by bringing the noble metal film and the substrate into contact with an etching agent.

A method for manufacturing a semiconductor component according to an application example of the present disclosure includes performing an etching process on the semiconductor substrate by the etching method according to the application example of the present disclosure, thereby manufacturing the semiconductor component.

### BRIEF DESCRIPTION OF THE DRAWINGS

FIG. 1 is a cross-sectional view showing a configuration of a semiconductor substrate according to an embodiment.

FIG. 2 shows an example of a Raman spectrum obtained from a DLC film.

FIG. 3 is a flowchart showing a configuration of an etching method according to an embodiment.

FIG. 4 is a cross-sectional view for illustrating the etching method shown in FIG. 3.

FIG. 5 is a cross-sectional view for illustrating the etching method shown in FIG. 3.

FIG. 6 is a cross-sectional view for illustrating the etching method shown in FIG. 3.

FIG. 7 is a cross-sectional view for illustrating the etching method shown in FIG. 3.

FIG. 8 is a cross-sectional view for illustrating the etching method shown in FIG. 3.

FIG. 9 is a cross-sectional view for illustrating the etching method shown in FIG. 3.

FIG. 10 is a cross-sectional view for illustrating the etching method shown in FIG. 3.

FIG. 11 is a cross-sectional view showing an example in which side etching occurs at an interface between a substrate and a DLC film.

FIG. 12 is a perspective view showing a configuration example of an inkjet head.

FIG. 13 is a perspective view showing a configuration example of a three-dimensional microchannel.

FIG. 14 is a cross-sectional view showing a configuration example of a crystal oscillator.

FIG. 15 is a cross-sectional view showing a configuration example of a gas sensor.

FIG. 16 is Table 1 showing the formation conditions for forming the DLC films for each sample No., the I(D)/I(G) of the DLC films, and the evaluation results of the fabricated semiconductor components.

### DESCRIPTION OF EMBODIMENTS

Hereinafter, a semiconductor substrate, an etching method, and a method for manufacturing a semiconductor component according to the present disclosure will be described in detail based on embodiments shown in the accompanying drawings.

### 1. Semiconductor Substrate

First, a semiconductor substrate according to an embodiment will be described.

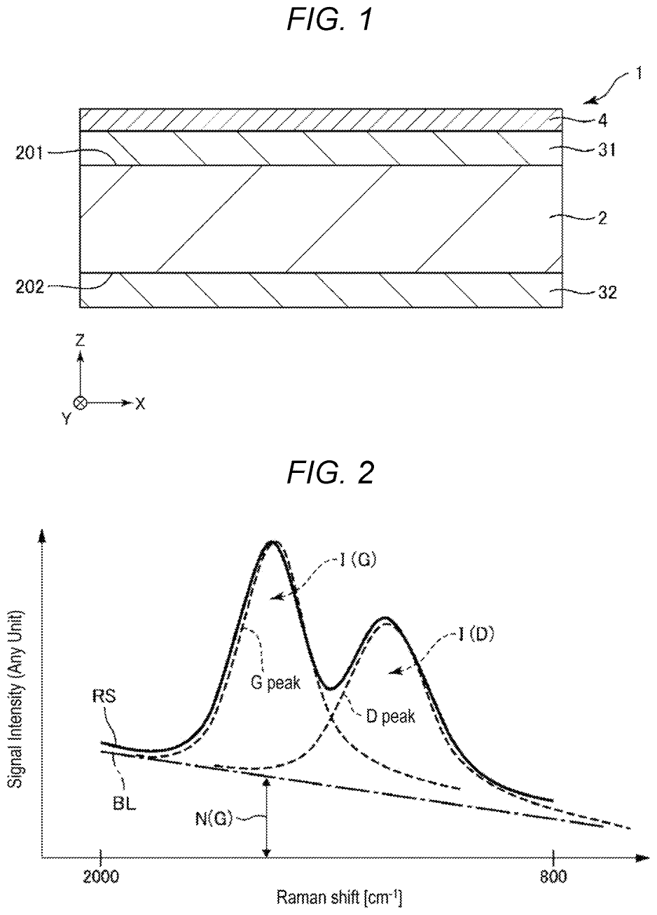

FIG. 1 is a cross-sectional view showing a configuration of a semiconductor substrate 1 according to an embodiment.

In each of the drawings of the present application, an X axis, a Y axis, and a Z axis are set as three axes orthogonal to one another, and are respectively indicated by arrows. A tip side of the arrow of each axis is referred to as a “plus side”, and a base end side thereof is referred to as a “minus side”. The Z-axis direction is also referred to as a “thickness direction”.

A semiconductor substrate 1 shown in FIG. 1 is a workpiece to be subjected to an etching process described later. The semiconductor substrate 1 shown in FIG. 1 includes a substrate 2, DLC films 31 and 32 (diamond-like carbon films), and an inorganic insulating film 4. The substrate 2 is made of a semiconductor material and has a first surface 201 and a second surface 202 that are front and back surfaces of each other. In the etching process described later, for example, a recess, a groove, or the like is formed in the first surface 201. Accordingly, a semiconductor component that realizes various functions can be manufactured.

The DLC film 31 is provided on the first surface 201, and the DLC film 32 is provided on the second surface 202. These function as a protective films that protect the substrate 2 in the etching process.

The inorganic insulating film 4 is provided on the Z-axis plus side of the DLC film 31 and covers the DLC film 31. The inorganic insulating film 4 is made of an inorganic material having insulating properties.

In such a semiconductor substrate 1, when a Raman spectrum of the DLC films 31 and 32 is obtained, the obtained Raman spectrum has peaks satisfying the following conditions.

FIG. 2 shows an example of a Raman spectrum obtained from the DLC films 31 and 32. In FIG. 2, the horizontal axis represents Raman shift and the vertical axis represents signal intensity.

In the Raman spectrum RS shown in FIG. 2, the intensity of the D peak derived from an sp³ hybrid orbital is defined as I(D), and the intensity of the G peak derived from an sp² hybrid orbital is defined as I(G). At this time, the Raman spectrum RS satisfies I(D)/I(G)≤2.1.

The sp³ hybrid orbital is an electron orbital associated with σ bonds, such as carbon-carbon bonds (diamond bonds) in diamond, and the sp² hybrid orbital is an electron orbital associated with both σ bonds and π bonds, such as carbon-carbon bonds (graphite bonds) in graphite. Diamond bonds form a three-dimensional network, and graphite bonds form a two-dimensional network.

When the ratio of I(D)/I(G) is within the above range, the DLC films 31 and 32 in which diamond bonds and graphite bonds are appropriately mixed can be realized. As a result, the coating properties of the DLC films 31 and 32 with respect to the substrate 2 are improved, and the elastic modulus is reduced, thereby reducing the stress in the DLC films 31 and 32. As a result, the DLC films 31 and 32 having good adhesion to the substrate 2 are obtained. The good adhesion of the DLC films 31 and 32 can contribute to suppression of side etching when the semiconductor substrate 1 is subjected to the etching process described later. Therefore, it is possible to improve the accuracy of the etching process.

### 1.1. Substrate

As described above, the substrate 2 is made of a semiconductor material and has a plate shape having the first surface 201 and the second surface 202 that are front and back surfaces of each other. The first surface 201 is a surface that extends along the XY plane and is located on the Z-axis plus side. The second surface 202 is a surface that extends along the XY plane and is located on the Z-axis minus side. Recesses, grooves, and the like are formed in the substrate 2 by the etching process described later. Thus, various semiconductor components are manufactured.

Examples of the semiconductor material include crystals of group IV elements such as silicon (Si) and germanium (Ge), crystals of compounds of group III elements and group V elements such as gallium arsenide (GaAs) and gallium nitride (GaN), and crystals of silicon carbide (SiC). In particular, a silicon single crystal is preferably used as the semiconductor material. That is, a silicon wafer is preferably used as the substrate 2. Here, the above “group” is a “group” in the short-period periodic table. The semiconductor material may be doped with impurities. For example, the substrate 2 may be a P-type silicon wafer or an N-type silicon wafer. When the semiconductor material is a crystalline material, the first surface 201 and the second surface 202 may each be parallel to various crystal planes.

Semiconductor elements, such as transistors, diodes, resistors, and capacitors, as well as circuits or the like, may be formed on the substrate 2.

The thickness of the substrate 2 is appropriately set according to the semiconductor component to be manufactured by the etching process and is not particularly limited, but is preferably 200 μm or more and 2000 μm or less, and more preferably 300 μm or more and 1000 μm or less.

### 1.2. DLC Film

The DLC films 31 and 32 are coating films containing diamond-like carbon (DLC). DLC is a generic term for substances having both diamond bonds and graphite bonds. DLC has good corrosion resistance. Accordingly, the DLC films 31 and 32 function as protective films for protecting the first surface 201 and the second surface 202 of the substrate 2 when the substrate 2 is subjected to the etching process in an etching method described later.

The Raman spectrum RS obtained for the DLC films 31 and 32 satisfies I(D)/I(G)≤2.1 as described above. The intensity I(D) of the D peak is derived from vibrations of an sp³ hybrid orbital, and corresponds to the area of the D peak identified by waveform separation of the Raman spectrum RS. The intensity I(G) of the G peak is derived from vibrations of an sp² hybrid orbital, and corresponds to the area of the G peak identified by waveform separation of the Raman spectrum RS. By optimizing I(D)/I(G), the DLC films 31 and 32 exhibiting good adhesion to the substrate 2 are obtained.

When I(D)/I(G) exceeds the above upper limit value, the balance between diamond bonding and graphite bonding deteriorates, and the elastic modulus of the DLC films 31 and 32 increases. As a result, the residual stress remaining in the DLC films 31 and 32 during film formation increases, and the adhesion of the DLC films 31 and 32 is reduced. When the adhesion is reduced, side etching is likely to occur when the semiconductor substrate 1 is subjected to an etching process.

The Raman spectrum RS is obtained, for example, as follows.

First, the semiconductor substrate 1 is set in a Raman spectroscopic apparatus. In the Raman spectroscopic apparatus, a Raman microscope that can pinpoint a minute region is particularly preferably used.

Next, a Raman spectrum RS of the DLC films 31 and 32 is obtained by the Raman spectroscopic apparatus. When the wavelength of the excitation light in the Raman spectroscopic apparatus is 532 nm, the Raman spectrum RS obtained from the DLC films 31 and 32 usually includes a D peak located near a Raman shift of 1350 cm⁻¹ and a G peak located near a Raman shift of 1551 cm⁻¹.

The intensity I(D) of the D peak and the intensity I(G) of the G peak are respectively obtained as follows.

First, a peak-deconvolution process is performed on the Raman spectrum RS using the software provided with the Raman spectrometer. Examples of the peak-deconvolution process include performing Gaussian fitting on the assumption that the D peak is derived from an sp³ hybrid orbital and the G peak is derived from an sp² hybrid orbital. By this peak-deconvolution process, the D peak and the G peak can be individually separated. Next, the area of the D peak is defined as an intensity I(D), and the area of the G peak is defined as an intensity I(G).

The intensity I(D) of the D peak and the intensity I(G) of the G peak of the DLC films 31 and 32 preferably satisfy I(D)/I(G)≤2.0, more preferably satisfy I(D)/I(G)≤1.5, and further preferably satisfy I(D)/I(G)≤1.0. As a result, the DLC films 31 and 32 having a lower elastic modulus and reduced stress are obtained. As a result, the adhesion of the DLC films 31 and 32 to the substrate 2 can be particularly enhanced, so that side etching can be particularly suppressed.

The intensity I(D) of the D peak and the intensity I(G) of the G peak of the DLC films 31 and 32 preferably satisfy 0.3≤I(D)/I(G), and more preferably satisfy 0.5≤I(D)/I(G). As a result, it is possible to ensure mechanical characteristics required for the coating properties of the DLC films 31 and 32. As a result, the continuity of the DLC films 31 and 32 can be improved, and side etching can be favorably suppressed.

The DLC films 31 and 32 preferably contain amorphous hydrogenated carbon. The amorphous hydrogenated carbon is amorphous carbon containing hydrogen, and can particularly reduce the elastic modulus of the DLC films 31 and 32. Therefore, in the DLC films 31 and 32 containing amorphous hydrogenated carbon, stress reduction is significant, and particularly good adhesion to the substrate 2 is exhibited. Further, the amorphous hydrogenated carbon imparts good insulating properties to the DLC films 31 and 32. Therefore, when the semiconductor substrate 1 is subjected to the etching process described later, the reaction between the substrate 2 and the etching agent can be stabilized.

In the present specification, “amorphous hydrogenated carbon” refers to DLC in which I(D)/I(G) is within the above range and which contains hydrogen. The content of hydrogen can be specified by analysis of the Raman spectrum RS. Specifically, in the Raman spectrum RS shown in FIG. 2, the baseline BL can be specified by the peak-deconvolution process described above. The baseline BL usually shows a tendency to increase as the Raman shift value increases. It is known that an increase in the baseline BL serves as an index of the hydrogen concentration. Specifically, when the increase width of the baseline BL at the position of the G peak is defined as N(G), log{N(G)/I(G)} relatively represents the hydrogen concentration. Then, the hydrogen concentration of the amorphous hydrogenated carbon is determined based on the value of log{N(G)/I(G)} obtained from a sample having a known hydrogen concentration.

The hydrogen concentration of the amorphous hydrogenated carbon is preferably 5 atomic % or more and 50 atomic % or less, and more preferably 10 atomic % or more and 40 atomic % or less. As a result, amorphous hydrogenated carbon capable of imparting particularly good adhesion and insulating properties to the DLC films 31 and 32 is obtained.

The thickness of the DLC films 31 and 32 is preferably 25 nm or more, more preferably 50 nm or more, and further preferably 65 nm or more. When the thickness of the DLC films 31 and 32 is within the above range, the coating properties of the DLC films 31 and 32 can be favorably ensured, and the DLC films 31 and 32 can effectively function as protective films.

The thickness of the DLC films 31 and 32 is preferably 120 nm or less, more preferably 110 nm or less, and further preferably 95 nm or less. When the thickness of the DLC films 31 and 32 is within the above range, an increase in the rigidity of the DLC films 31 and 32 can be suppressed, thereby reducing stress.

When the thickness of the DLC films 31 and 32 is less than the above lower limit value, the DLC films 31 and 32 may become discontinuous, and their function as protective films may be reduced. On the other hand, when the thickness of the DLC films 31 and 32 exceeds the above upper limit value, the residual stress in the DLC films 31 and 32 during film formation increases, and the adhesion of the DLC films 31 and 32 to the substrate 2 may be reduced.

The thickness of the DLC films 31 and 32 is measured as follows.

First, the semiconductor substrate 1 is cut in the thickness direction, and the cut surface is polished. Next, the polished surface is observed under magnification, and the thickness of the DLC films 31 and 32 is measured at 10 or more locations. For observation under magnification, for example, a scanning electron microscope can be used. The average value of the measured values is taken as the thickness of the DLC films 31 and 32.

The DLC film 32 may be provided as necessary, or may be omitted. In contrast, since the semiconductor substrate 1 includes the DLC films 31 and 32, both the first surface 201 and the second surface 202 can be favorably protected in the etching process. Therefore, a highly accurate etching process can be performed. In addition, since the semiconductor substrate 1 includes the DLC films 31 and 32, warpage occurring in the semiconductor substrate 1 can be suppressed as compared with a case where only the DLC film 31 is provided.

### 1.3. Inorganic Insulating Film

The inorganic insulating film 4 is provided on the Z-axis plus side of the DLC film 31 and covers the DLC film 31. The inorganic insulating film 4 is made of an inorganic material having insulating properties. Such an inorganic insulating film 4 contributes to improving the insulating properties between the etching agent and the DLC film 31 when the semiconductor substrate 1 is subjected to an etching process. Accordingly, the etching reaction can be stabilized.

In addition, the inorganic insulating film 4 contributes to improving the peelability of the resist film when the resist film is peeled off from the inorganic insulating film 4 after the DLC film 31 and the inorganic insulating film 4 are patterned in the etching process described later.

Examples of the inorganic material include silicon oxide, aluminum oxide, titanium oxide, magnesium oxide, hafnium oxide, tantalum oxide, silicon oxynitride, and silicon nitride, and one or more composite materials thereof are used.

The inorganic insulating film 4 is preferably a silicon oxide film. Silicon oxide is an inorganic oxide represented by SiOx (0<x≤2) and has particularly good insulating properties. When the inorganic insulating film 4 is a silicon oxide film, the inorganic insulating film 4 can be etched together with the substrate 2 when the substrate 2 is etched. Therefore, it is also advantageous because removal of the inorganic insulating film 4 is not required.

The thickness of the inorganic insulating film 4 is preferably 20 nm or more and 300 nm or less, and more preferably 50 nm or more and 100 nm or less. When the thickness of the inorganic insulating film 4 is within the above range, the insulating properties and the corrosion resistance of the inorganic insulating film 4 can be sufficiently ensured, and the residual stress during film formation of the inorganic insulating film 4 can be kept low.

The thickness of the inorganic insulating film 4 is measured as follows.

First, the semiconductor substrate 1 is cut in the thickness direction, and the cut surface is polished. Next, the polished surface is observed under magnification, and the thickness of the inorganic insulating film 4 is measured at 10 or any locations. For observation under magnification, for example, a scanning electron microscope can be used. The average value of the measured values is taken as the thickness of the inorganic insulating film 4.

The inorganic insulating film 4 may be provided as necessary, or may be omitted. In FIG. 1, the inorganic insulating film 4 is provided only on the Z-axis plus side of the DLC film 31, but the inorganic insulating film 4 may also be provided on the Z-axis minus side of the DLC film 32.

### 2. Etching Method

Next, the etching method according to an embodiment will be described.

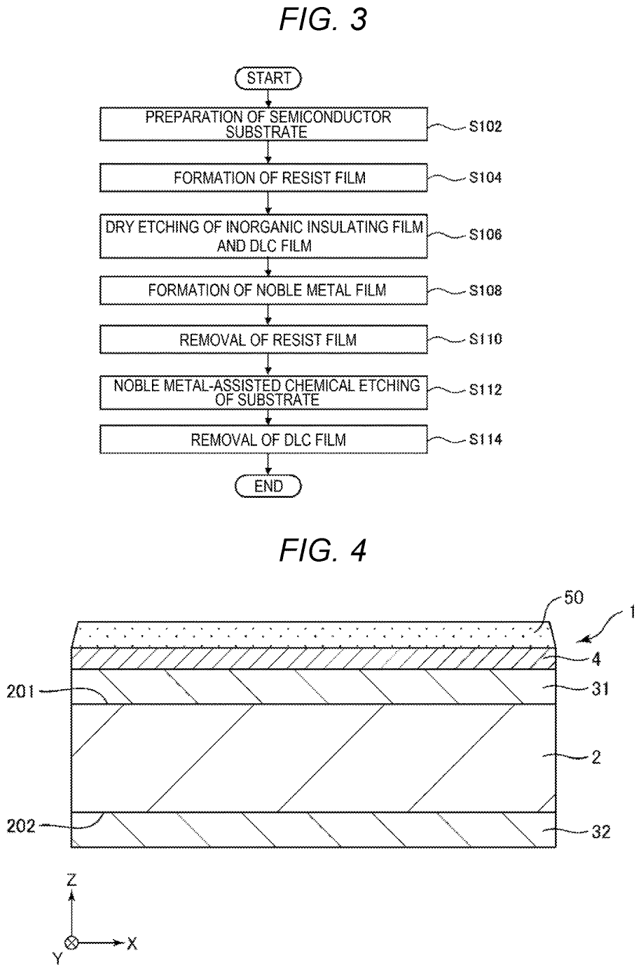

FIG. 3 is a flowchart showing a configuration of an etching method according to an embodiment. FIGS. 4 to 10 are respectively cross-sectional views illustrating the etching method shown in FIG. 3.

The etching method shown in FIG. 3 includes a semiconductor substrate preparation step S102, a resist film forming step S104 (first step), a dry etching step S106 (second step), a noble metal film forming step S108 (third step), a resist film removing step S110, a noble metal-assisted chemical etching step S112 (fourth step), and a DLC film removing step S114.

In the resist film forming step S104, a resist film 5 having an opening 51 in the first region R1 is formed on the semiconductor substrate 1 prepared in the semiconductor substrate preparation step S102. In the dry etching step S106, the DLC film 31 corresponding to the first region R1 is etched. Further, in the noble metal film forming step S108, a porous noble metal film 60 is formed on the first surface 201 (surface) of the substrate 2 corresponding to the first region R1. In the noble metal-assisted chemical etching step S112, the noble metal film 60 and the substrate 2 are brought into contact with the etching agent to etch the substrate 2 using the noble metal film 60 as a catalyst.

According to such a configuration, since the adhesion between the substrate 2 and the DLC film 31 is good, side etching at the interface between the substrate 2 and the DLC film 31 can be suppressed. Therefore, in the noble metal-assisted chemical etching step S112, a highly accurate etching process can be performed. As a result, a semiconductor component having high surface processing accuracy, such as recesses or grooves, can be manufactured.

### 2.1. Semiconductor Substrate Preparation Step

In the semiconductor substrate preparation step S102, the semiconductor substrate 1 according to the embodiment is prepared. The semiconductor substrate 1 is fabricated as follows.

First, the DLC film 31 is formed on the first surface 201 of the substrate 2, and the DLC film 32 is formed on the second surface 202. Examples of methods for forming the DLC films 31 and 32 include a chemical vapor deposition (CVD) method, a sputtering method, an ionization vapor deposition method, and an ion plating method. Among these, the CVD method is preferably used. In the CVD method, since the DLC films 31 and 32 can be formed at a relatively low temperature, the low-stress DLC films 31 and 32 can be efficiently formed.

Examples of the CVD method include a plasma CVD method and a thermal CVD method, and the plasma CVD method is preferably used. In the plasma CVD method, the DLC films 31 and 32 can be formed particularly at a low temperature.

Examples of the plasma CVD method include a capacitively coupled plasma CVD method and an inductively coupled plasma CVD method. In these plasma CVD methods, I(D)/I(G) is within the above range, and the DLC films 31 and 32 containing amorphous hydrogenated carbon can be efficiently formed.

The capacitively coupled plasma CVD method forms the DLC films 31 and 32 by decomposing and depositing a raw material gas using plasma generated by parallel plate electrodes.

In the inductively coupled plasma CVD method, plasma is generated by electromagnetic induction in an inductively coupled plasma (ICP) source, and the plasma is used to decompose and deposit a raw material gas to form the DLC films 31 and 32.

As a raw material gas for forming the DLC films 31 and 32, for example, a hydrocarbon gas such as methane, acetylene, toluene, benzene, butylbenzene, cyclopentane, or adamantane is used. Accordingly, the DLC films 31 and 32 having I(D)/I(G) within the above range can be efficiently formed. Since the hydrocarbon gas contains carbon atoms and hydrogen atoms, the DLC films 31 and 32 containing amorphous hydrogenated carbon can be efficiently formed. A sub-gas such as hydrogen or argon may be added to the raw material gas as necessary.

The film-forming temperature for forming the DLC films 31 and 32 is preferably 10 °C or higher and 200 °C or lower, and more preferably 20 °C or higher and 150 °C or lower. Accordingly, since the DLC films 31 and 32 can be formed at a relatively low temperature, the residual stress in the DLC films 31 and 32 can be kept low. The film-forming temperature is the temperature of the substrate 2 or the vicinity thereof. In addition, by setting the film-forming temperature within the above range, the DLC films 31 and 32 having I(D)/I(G) within the above range and the DLC films 31 and 32 containing amorphous hydrogenated carbon can be efficiently formed.

The discharge output in the plasma CVD method is not particularly limited, but is preferably 30 W or more and 1000 W or less, and more preferably 50 W or more and 800 W or less. The atmospheric pressure in the plasma CVD method is not particularly limited, but is preferably 0.1 Pa or more and 100 Pa or less.

By setting the discharge output and the atmospheric pressure within the above ranges, the DLC films 31 and 32 having I(D)/I(G) within the above ranges and the DLC films 31 and 32 containing amorphous hydrogenated carbon can be efficiently formed.

I(D)/I(G) tends to be reduced by lowering the film-forming temperature or reducing the discharge output. On the other hand, I(D)/I(G) tends to increase by increasing the film-forming temperature or increasing the discharge output. Therefore, I(D)/I(G) can be adjusted by these manufacturing conditions.

In the semiconductor substrate preparation step S102, after the DLC films 31 and 32 are formed, the inorganic insulating film 4 is formed on the DLC film 31. Examples of methods for forming the inorganic insulating film 4 include a CVD method, a sputtering method, and a vacuum deposition method. Among these, the CVD method is preferably used, and the plasma CVD method is more preferably used.

Note that, in the present specification, “forming B on A” means either forming a state in which A and B are in contact with each other or forming a state in which any member is interposed between A and B.

Examples of raw materials for forming the inorganic insulating film 4 include monosilane, polysilazane, and organic silanes such as tetraethoxysilane.

The film-forming temperature for forming the inorganic insulating film 4 is preferably 60 °C or more and 400 °C or less, and more preferably 80 °C or more and 300 °C or less. Thus, since the inorganic insulating film 4 can be formed at a relatively low temperature, the residual stress in the inorganic insulating film 4 can be kept low.

### 2.2. Resist Film Forming Step

As shown in FIG. 4, the resist film forming step S104 (first step) includes a process of forming a photosensitive film 50 on the inorganic insulating film 4. For example, a photoresist material having photosensitivity is used for the photosensitive film 50. The photosensitive film 50 is formed, for example, by spin coating or spray coating.

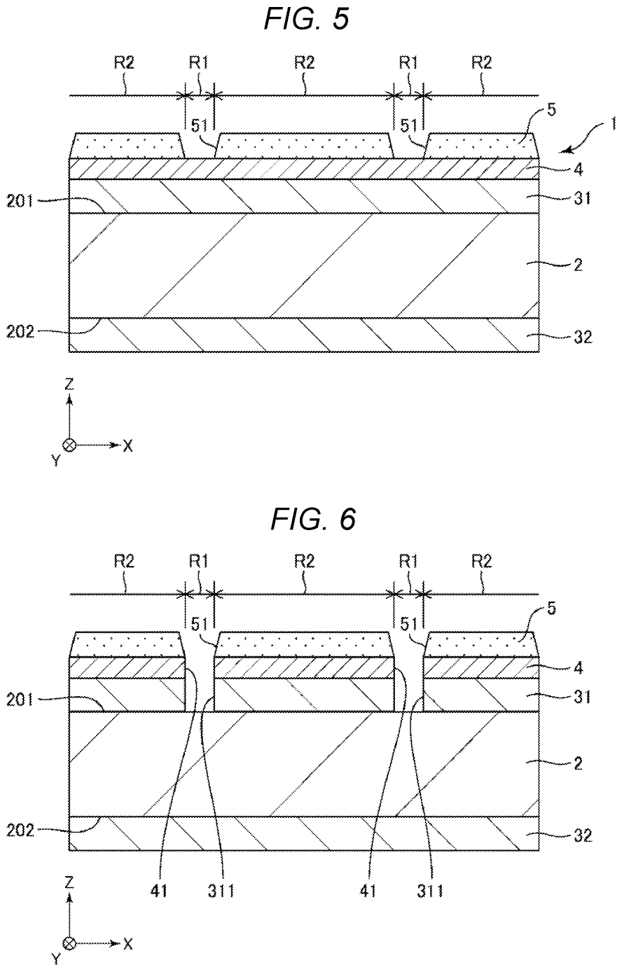

In the resist film forming step S104 (first step), the photosensitive film 50 is then subjected to an exposure process and a development process. Thus, the photosensitive film 50 is patterned to obtain the resist film 5 shown in FIG. 5. The resist film 5 has the opening 51 in the first region R1 and covers the second region R2. The first region R1 is a region set in the substrate 2, in which an etching process is to be performed on the substrate 2 in the noble metal-assisted chemical etching step S112 described later. The second region R2 is a region adjacent to the first region R1 (a region other than the first region R1). In the present specification, “corresponding to the first region R1” refers to being in a positional relationship of overlapping the first region R1 when viewed from the Z-axis. The above descriptions are similarly applied to a case of the second region R2.

The thickness of the resist film 5 is not particularly limited, but is, for example, 0.5 μm or more and 10 μm or less, and preferably 1 μm or more and 5 μm or less.

### 2.3. Dry Etching Step

As shown in FIG. 6, the dry etching step S106 (second step) includes a process of etching (removing) the DLC film 31 and the inorganic insulating film 4 corresponding to the opening 51. As a result, a through hole 311 is formed in the DLC film 31, and a through hole 41 is formed in the inorganic insulating film 4.

In the dry etching step S106, dry etching is preferably used as an etching method. For the dry etching, reactive ion etching (RIE) is preferably used. RIE enables highly accurate etching in which the opening 51 of the resist film 5 is accurately reflected.

Examples of etching gases include fluorocarbon-based gases such as CHF₃ and CF₄, oxygen gas, and argon gas. In addition, other gases may be used in combination for etching. As an example, the inorganic insulating film 4 is etched using a fluorocarbon-based gas to form the through hole 41, and, after that, the DLC film 31 is etched using oxygen gas to form the through hole 311.

### 2.4. Noble Metal Film Forming Step

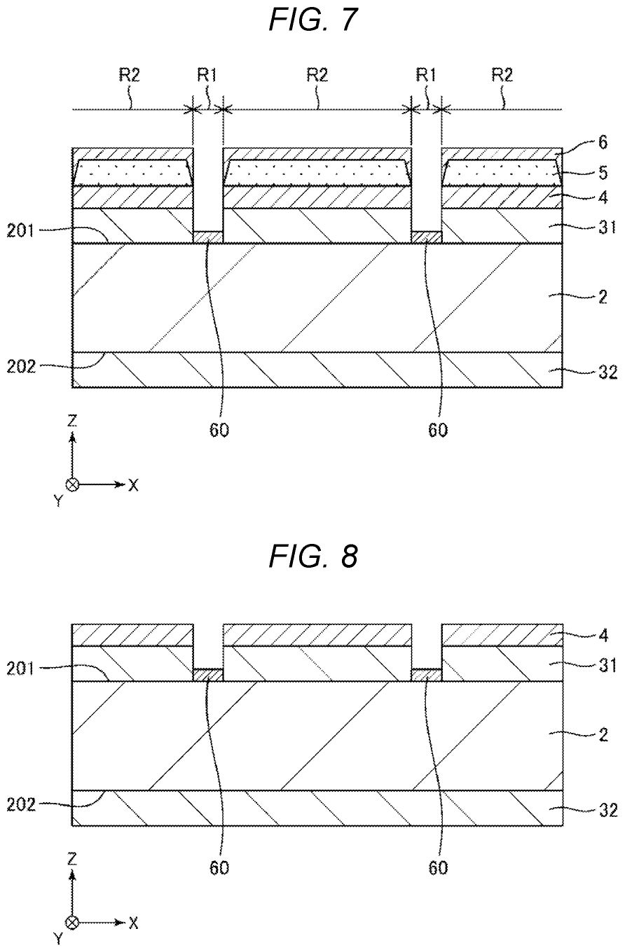

In the noble metal film forming step S108 (third step), as shown in FIG. 7, the noble metal film 6 is formed on the resist film 5. When the noble metal film 6 is formed, the noble metal film 60 is formed on the first surface 201 (surface) of the substrate 2 in the first region R1.

Examples of methods for forming the noble metal films 6 and 60 include various vapor deposition methods such as a sputtering method and a vacuum deposition method, and various plating methods.

The noble metal films 6 and 60 are porous. In the present specification, the term “porous” refers to a property of a film that is non-continuous, has pores penetrating in the thickness direction, and is permeable to liquid.

Examples of methods for forming such noble metal films 6 and 60 include a method for stopping film formation before forming a continuous film to obtain a discontinuous film, a method for making porous by patterning, and other methods.

The thicknesses of the noble metal films 6 and 60 are not particularly limited, and each is preferably 3 nm or more and 100 nm or less, and more preferably 10 nm or more and 30 nm or less. This improves the permeability of the noble metal film 60 to the etching agent.

The thicknesses of each of the noble metal films 6 and 60 is measured as follows.

First, a member on which noble metal films 6 and 60 are formed is cut in the thickness direction, and the cut surface is polished. Next, the polished surface is observed under magnification, and the thicknesses of the portions corresponding to the noble metal films 6 and 60 are each measured at 10 or locations. For observation under magnification, for example, a scanning electron microscope can be used. The average value of the measured values is taken as the thicknesses of each of the noble metal films 6 and 60.

Examples of noble metals include single metals such as Au, Ag, Pt, Pd, Rd, and Rh, or alloys containing two or more thereof.

### 2.5. Resist Film Removing Step

In the resist film removing step S110, as shown in FIG. 8, the resist film 5 is removed. When the resist film 5 is removed, the noble metal film 6 provided thereon can also be removed by lift-off. For example, a stripping solution is used to remove the resist film 5.

When the semiconductor substrate 1 includes the inorganic insulating film 4, the resist film 5 can be efficiently removed in this step because the resist film 5 and the inorganic insulating film 4 exhibit good peelability.

Further, the resist film removing step S110 may be performed as necessary, and may be omitted. When the resist film removing step S110 is omitted, the noble metal-assisted chemical etching step S112 may be performed with the resist film 5 and the noble metal film 6 provided thereon.

Meanwhile, when the resist film removing step S110 is performed, the noble metal film 6 that is not in contact with the substrate 2 can be removed in the noble metal-assisted chemical etching step S112. This can prevent the noble metal film 6 from unintentionally acting as a catalyst in the noble metal-assisted chemical etching step S112. This can suppress an excessive reaction caused by the noble metal film 6 acting as a catalyst. As a result, an unintended portion of the substrate 2 can be prevented from being etched, and a reduction in processing accuracy of a portion to be etched can also be prevented.

### 2.6. Noble Metal-Assisted Chemical Etching Step

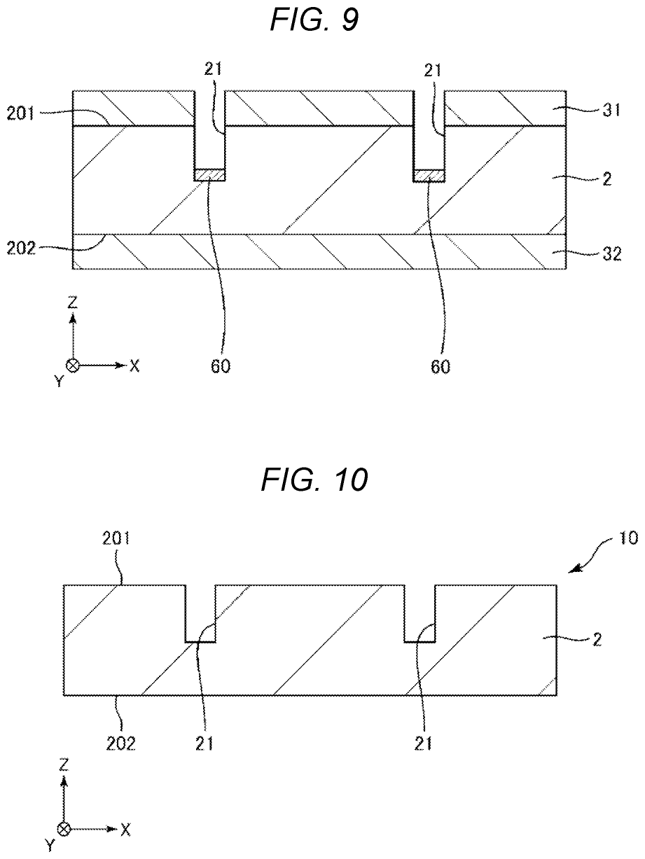

In the noble metal-assisted chemical etching step S112 (fourth step), the noble metal film 60 and the substrate 2 are brought into contact with the etching agent. Accordingly, the substrate 2 and the etching agent are reacted using the noble metal film 60 as a catalyst, such that the first surface 201 of the substrate 2 is etched toward the Z-axis minus side. The etching using the noble metal film 60 as a catalyst is referred to as noble metal-assisted chemical etching. In the noble metal-assisted chemical etching, the substrate 2 adjacent to the noble metal film 60 is oxidized, and an oxide generated thereby is dissolved and removed. Then, the noble metal film 60 moves to the Z-axis minus side. As the dissolution and removal of the oxide and the movement of the noble metal film 60 are repeated, the substrate 2 can be selectively etched in the thickness direction. As a result, as shown in FIG. 9, a recess 21 opening in the first surface 201 is formed. The recess 21 may be formed so as to penetrate the substrate 2.

Further, since the inorganic insulating film 4 is formed on the semiconductor substrate 1, the insulating properties between the etching agent and the DLC film 31 can be further enhanced. Therefore, even in an environment where the etching reaction is excessive, the insulating properties of the inorganic insulating film 4 can stabilize the reaction.

As the etching agent, for example, a solution containing an oxidizing agent and hydrogen fluoride is used. The etching agent is not limited thereto.

In the noble metal-assisted chemical etching step S112, the inorganic insulating film 4 is dissolved in the etching agent. Thus, the inorganic insulating film 4 is removed as shown in FIG. 9.

Since the DLC films 31 and 32 have excellent adhesion to the substrate 2, the probability of the etching agent entering the interface between the substrate 2 and the DLC films 31 and 32 is reduced. Therefore, side etching at the interface can be suppressed.

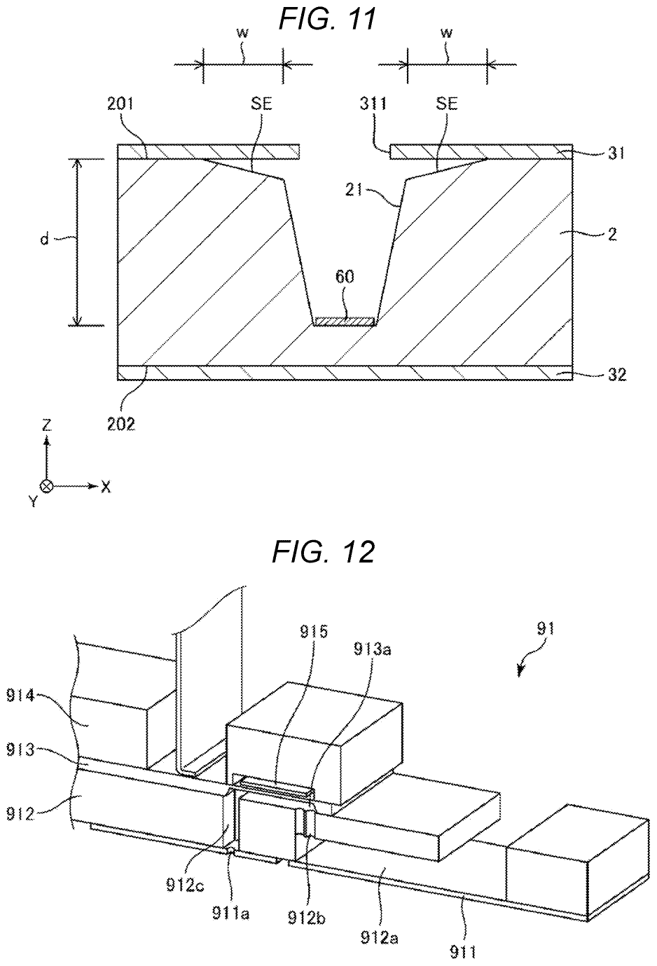

FIG. 11 is a cross-sectional view showing an example in which side etching SE occurs at the interface between the substrate 2 and the DLC film 31.

The side etching SE shown in FIG. 11 spreads along the interface between the substrate 2 and the DLC film 31 starting from the opening of the recess 21. When such side etching SE occurs, the accuracy of the recess 21 is reduced. The side etching SE can be attributed to reduced adhesion of the DLC film 31 to the substrate 2 and entry of the etching agent into the interface.

In contrast, in the present embodiment, the adhesion between the substrate 2 and the DLC films 31 and 32 is good. Therefore, the probability of the etching agent entering the interface can be reduced. Accordingly, since the side etching SE can be suppressed, a reduction in the accuracy of the recess 21 can be suppressed.

The depth of the recess 21 shown in FIG. 11 is defined as d, and the width of the side etching SE generated in the recess 21 is defined as w. In the present embodiment, it is possible to form the recess 21 that satisfies w/d≤0.02. Even when the plurality of recesses 21 are arranged adjacent to each other, the recesses 21 can be prevented from interfering with each other. Therefore, this contributes to realizing the semiconductor component 10 in which the recesses 21 are arranged at a high density.

After the noble metal-assisted chemical etching, the noble metal film 60 is brought into contact with a noble metal solution. Thus, the remaining noble metal film 60 can be removed. Examples of the noble metal solution include a mixed acid of hydrochloric acid and nitric acid.

### 2.7. DLC Film Removing Step

In the DLC film removing step S114, as shown in FIG. 10, the DLC films 31 and 32 are removed. For example, dry etching or ashing is used to remove the DLC films 31 and 32. In the ashing, O₂ ashing is preferably used.

The semiconductor component 10 shown in FIG. 10 can be obtained by removing the DLC films 31 and 32. The semiconductor component 10 is a component in which the recess 21 is formed in the first surface 201 of the substrate 2 by an etching process. The recess 21 is excellent in accuracy even at a high aspect ratio by noble metal-assisted chemical etching. The recess 21 may extend through.

### 3. Method for Manufacturing Semiconductor Component

The method for manufacturing a semiconductor component according to the embodiment is a method for performing an etching process on the semiconductor substrate 1 by the above etching method, thereby manufacturing the semiconductor component 10.

According to such a method, since the adhesion between the substrate 2 and the DLC films 31 and 32 in the semiconductor substrate 1 is good, the probability that the etching agent enters the interface between the substrate 2 and the DLC films 31 and 32 can be reduced. Therefore, the side etching SE can be suppressed, and a semiconductor component 10 having high surface processing accuracy, such as a recess 21, can be manufactured. The shape of the surface processing is not limited to the recess 21, and may be any shape.

Examples of the manufactured semiconductor component 10 include a component for an inkjet head, a component for a three-dimensional microchannel, a component for a crystal oscillator, a component for a sensor, a component for a micro electro mechanical systems (MEMS) element, a component for a semiconductor device, and a component for a light receiving and emitting element.

FIG. 12 is a perspective view showing a configuration example of an inkjet head 91.

The inkjet head 91 shown in FIG. 12 includes a nozzle substrate 911, a communication substrate 912, a cavity substrate 913, a sealing substrate 914, and a piezoelectric element 915.

A nozzle 911a for ejecting ink is formed in the nozzle substrate 911. In addition, cavity portions such as a reservoir 912a, a supply port 912b, and a communication port 912c are formed in the communication substrate 912. Cavity portions such as an ink pressure chamber 913a are formed in the cavity substrate 913.

The semiconductor component 10 described above can be used for at least one of the nozzle substrate 911, the communication substrate 912, the cavity substrate 913, and the sealing substrate 914.

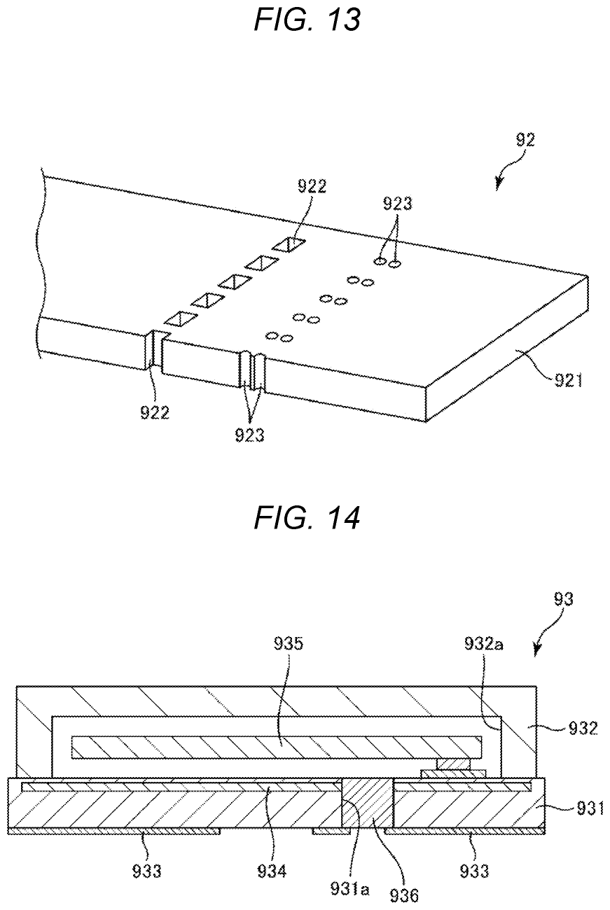

FIG. 13 is a perspective view showing a configuration example of a three-dimensional microchannel 92.

The three-dimensional microchannel 92 shown in FIG. 13 includes a plate-shaped base 921 and through holes 922 and 923 that penetrate the base 921 in the thickness direction. The three-dimensional microchannel 92 is a component capable of integrating, for example, reaction operations, separation operations, detection operations, and the like for biotechnology, medical treatment, analysis, and the like. The semiconductor component 10 described above can be used for such a three-dimensional microchannel 92.

FIG. 14 is a cross-sectional view showing a configuration example of a crystal oscillator 93.

The crystal oscillator 93 shown in FIG. 14 includes a base 931, a lid 932, an external terminal 933, a circuit 934, a quartz crystal unit 935, and a through electrode 936.

A through hole 931a is formed in the base 931. The through hole 931a is filled with the through electrode 936. The through electrode 936 connects the circuit 934 provided in the base 931 and the external terminal 933 to each other.

The cavity 932a is formed in the lid 932. The quartz crystal unit 935 is accommodated in the cavity 932a.

The semiconductor component 10 described above can be used for at least one of the base 931 and the lid 932.

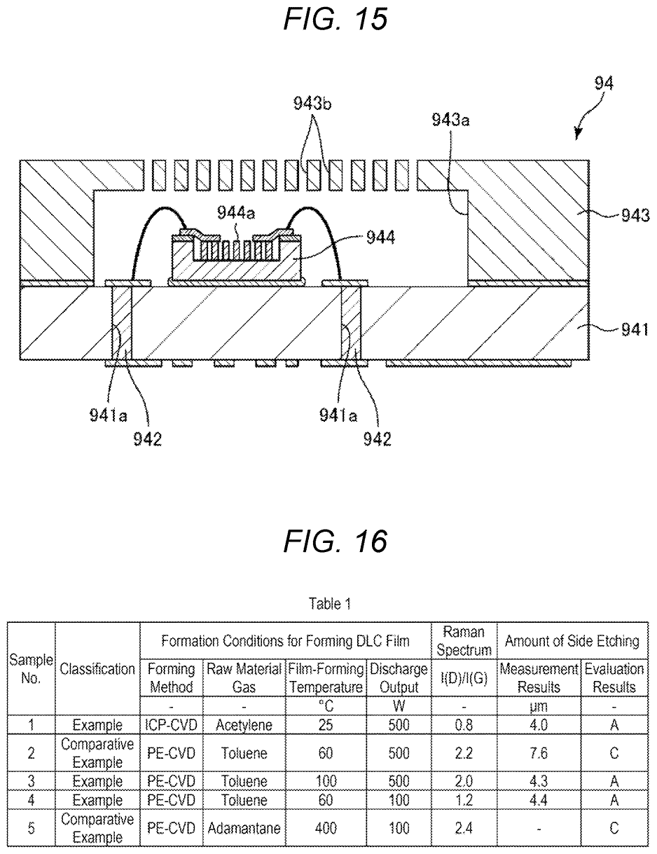

FIG. 15 is a cross-sectional view showing a configuration example of a gas sensor 94.

The gas sensor 94 shown in FIG. 15 includes a circuit substrate 941, a through electrode 942, a filter cover 943, and a gas sensor chip 944.

The through hole 941a is formed in the circuit substrate 941. The through hole 941a is filled with the through electrode 942.

A cavity 943a and a vent hole 943b are formed in the filter cover 943.

A nanocolumn structure 944a is formed in the gas sensor chip 944.

The semiconductor component 10 described above can be used for at least one of the circuit substrate 941, the filter cover 943, and the gas sensor chip 944.

### 4. Effects of Embodiment

As described above, the semiconductor substrate 1 according to the embodiment includes the substrate 2 and the DLC films 31 and 32 (diamond-like carbon films). The substrate 2 is made of a semiconductor material and has a first surface 201 and a second surface 202 that are front and back surfaces of each other. The DLC film 31 is provided on the first surface 201 of the substrate 2, and the DLC film 32 is provided on the second surface 202. In the Raman spectrum RS of the DLC film 31, when the intensity of the D peak derived from the sp³ hybrid orbital is defined as I(D) and the intensity of the G peak derived from the sp² hybrid orbital is defined as I(G), I(D)/I(G)≤2.1 is satisfied.

According to such a configuration, since the ratio of I(D)/I(G) is optimized, the DLC films 31 and 32 in which diamond bonds and graphite bonds are appropriately mixed can be realized. As a result, the coating properties of the DLC films 31 and 32 with respect to the substrate 2 are improved, and the elastic modulus is reduced, thereby reducing the stress in the DLC films 31 and 32. As a result, the DLC films 31 and 32 having good adhesion to the substrate 2 are obtained. The good adhesion of the DLC films 31 and 32 can contribute to suppression of side etching when the semiconductor substrate 1 is subjected to an etching process.

In the semiconductor substrate 1 according to the embodiment, the DLC films 31 and 32 preferably contain amorphous hydrogenated carbon.

According to such a configuration, the elastic modulus of the DLC films 31 and 32 can be particularly reduced. Therefore, the stress of the DLC films 31 and 32 is significantly reduced, and particularly good adhesion to the substrate 2 is exhibited. Further, the amorphous hydrogenated carbon imparts good insulating properties to the DLC films 31 and 32. Therefore, when the semiconductor substrate 1 is subjected to an etching process, the reaction between the substrate 2 and the etching agent can be stabilized.

In the semiconductor substrate 1 according to the embodiment, the intensity I(D) of the D peak and the intensity I(G) of the G peak preferably satisfy 0.3≤I(D)/I(G).

According to such a configuration, it is possible to ensure mechanical characteristics required for the coating properties of the DLC films 31 and 32. As a result, the continuity of the DLC films 31 and 32 can be improved, and side etching can be favorably suppressed.

In the semiconductor substrate 1 according to the embodiment, the intensity I(D) of the D peak and the intensity I(G) of the G peak preferably satisfy I(D)/I (G)≤1.0.

According to such a configuration, the DLC films 31 and 32 having a lower elastic modulus and reduced stress are obtained. As a result, the adhesion of the DLC films 31 and 32 to the substrate 2 can be particularly enhanced, so that side etching can be particularly suppressed.

In the semiconductor substrate 1 according to the embodiment, the thicknesses of each of the DLC films 31 and 32 is preferably 25 nm or more.

According to such a configuration, the coating properties of the DLC films 31 and 32 can be favorably ensured, and the DLC films 31 and 32 can effectively function as protective films.

In the semiconductor substrate 1 according to the embodiment, the thicknesses of each of the DLC films 31 and 32 is preferably 120 nm or less.

According to such a configuration, an increase in the rigidity of the DLC films 31 and 32 can be suppressed, thereby reducing the stress in the DLC films.

The semiconductor substrate 1 according to the embodiment may further include the inorganic insulating film 4 provided on the DLC films 31 and 32.

According to such a configuration, when the semiconductor substrate 1 is subjected to an etching process, the inorganic insulating film 4 contributes to improving the insulating properties between the etching agent and the DLC film 31. When the resist film 5 is peeled off after being formed on the inorganic insulating film 4, good peelability is obtained.

In the semiconductor substrate 1 according to the embodiment, the inorganic insulating film 4 is preferably a silicon oxide film.

According to such a configuration, the insulating properties of the inorganic insulating film 4 can be particularly enhanced. When the substrate 2 is etched, the inorganic insulating film 4 can be etched together with the substrate 2. Therefore, it is not necessary to remove the inorganic insulating film 4.

The semiconductor substrate 1 according to the embodiment may include the DLC film 31 provided on the first surface 201 and the DLC film 32 provided on the second surface 202.

According to such a configuration, both the first surface 201 and the second surface 202 can be favorably protected in the etching process. Therefore, a highly accurate etching process can be performed. In addition, since the semiconductor substrate 1 includes the DLC films 31 and 32, warpage occurring in the semiconductor substrate 1 can be suppressed as compared with a case where only the DLC film 31 is provided.

The etching method according to the embodiment is a method for etching the semiconductor substrate 1 according to the embodiment, and includes the resist film forming step S104 (first step), the dry etching step S106 (second step), the noble metal film forming step S108 (third step), and the noble metal-assisted chemical etching step S112 (fourth step). In the resist film forming step S104, the resist film 5 is formed on the DLC film 31 so as to have the opening 51 in the first region R1 of the substrate 2 and cover the second region R2 of the substrate 2. In the dry etching step S106, the DLC film 31 corresponding to the opening 51 is etched. In the noble metal film forming step S108, the porous noble metal film 60 is formed on the first surface 201 (surface) of the substrate 2 corresponding to the first region R1. In the noble metal-assisted chemical etching step S112, the noble metal film 60 and the substrate 2 are brought into contact with the etching agent to etch the substrate 2 using the noble metal film 60 as a catalyst.

According to such a configuration, since the adhesion between the substrate 2 and the DLC film 31 is good, side etching at the interface between the substrate 2 and the DLC film 31 can be suppressed. Therefore, in the noble metal-assisted chemical etching step S112, a highly accurate etching process can be performed. As a result, a semiconductor component 10 having high surface processing accuracy, such as recesses or grooves, can be manufactured.

In the etching method according to the embodiment, the semiconductor substrate 1 may further include the inorganic insulating film 4 provided on the DLC film 31 (diamond-like carbon film). In this case, the resist film forming step S104 (first step) includes a process of forming the resist film 5 on the inorganic insulating film 4. The dry etching step S106 (second step) includes a process of removing the inorganic insulating film 4 corresponding to the first region R1.

According to such a configuration, when the semiconductor substrate 1 is subjected to an etching process in the noble metal-assisted chemical etching step S112 (fourth step), the inorganic insulating film 4 contributes to improving the insulating properties between the etching agent and the DLC film 31. When the resist film 5 is peeled off in the resist film removing step S110 after being formed on the inorganic insulating film 4, good peelability is obtained.

In the etching method according to the embodiment, the noble metal-assisted chemical etching step S112 (fourth step) includes a process of forming the recess 21 in the substrate 2 by etching the substrate 2. When the depth of the recess 21 is defined as d and the width of the side etching generated in the recess 21 is defined as w, the recess 21 may be formed to satisfy w/d≤0.02.

Even when the plurality of recesses 21 are arranged adjacent to each other, the recesses 21 can be prevented from interfering with each other. Therefore, this contributes to realizing the semiconductor component 10 in which the recesses 21 are arranged at a high density.

The method for manufacturing a semiconductor component according to the embodiment includes performing an etching process on the semiconductor substrate 1 by the etching method according to the embodiment, thereby manufacturing the semiconductor component 10.

According to such a configuration, a semiconductor component 10 having high surface processing accuracy, such as a recess 21, can be manufactured.

Although the semiconductor substrate, the etching method, and the method for manufacturing a semiconductor component according to the present disclosure are described based on the shown embodiments, the present disclosure is not limited thereto.

For example, the semiconductor substrate according to the disclosure may be obtained by adding any component to the embodiment. In addition, in the etching method and the method for manufacturing a semiconductor component according to the present disclosure, any desired step may be added to the embodiment.

### EXAMPLES

Next, specific examples of the present disclosure will be described.

### 5. Fabrication of Semiconductor Component

First, a silicon single crystal substrate having a conductivity type of P type and plane orientation (110) was prepared as a substrate.

Next, a DLC film having a thickness of 80 nm was formed at both surfaces of the silicon single crystal substrate. The forming method, the raw material gas, the film-forming temperature, and the discharge output are as shown in Table 1 (FIG. 16).

FIG. 16 is Table 1 showing the formation conditions for forming the DLC films for each sample No., the I(D)/I(G) of the DLC films, and the evaluation results of the fabricated semiconductor components. In Table 1, those corresponding to the present disclosure are each indicated by “Example”, and those not corresponding to the present disclosure are each indicated by “Comparative Example”.

Next, a silicon oxide film having a thickness of 70 nm was formed as an inorganic insulating film on the DLC film on one surface of the silicon single crystal substrate. A plasma CVD method was used to form the silicon oxide film.

Next, a photosensitive film was formed on the silicon oxide film. A photoresist material was used for forming the photosensitive film. Thereafter, the photosensitive film was subjected to an exposure process and a development process to form a patterned resist film.

Next, dry etching was performed via the resist film to form through holes in the silicon oxide film and the DLC film, respectively.

Next, Au was vapor-deposited to form a noble metal film having a thickness of 20 nm. A vacuum deposition method was used for the deposition of Au.

Next, the resist film was removed using a stripping solution. Accordingly, the unnecessary noble metal film was removed by lift-off.

Next, noble metal-assisted chemical etching was performed by bringing the etching agent into contact with the noble metal film and the silicon single crystal substrate, thereby forming a plurality of recesses in the silicon single crystal substrate. The design shape of the opening of the recess was a 40-μm square, and the pitch between adjacent recesses was set to 83 μm. Thereafter, the remaining noble metal film was removed using a noble metal solution.

Next, the DLC film was subjected to O₂ ashing to remove the DLC film. As described above, a semiconductor component in which a plurality of recesses were formed was obtained.

### 6. Evaluation of Semiconductor Substrate

A Raman spectrum was obtained for the silicon single crystal substrate (semiconductor substrate) on which the DLC film was formed.

Next, a peak-deconvolution process was performed on the obtained Raman spectrum to acquire the intensity I(D) of the D peak and the intensity I(G) of the G peak.

Next, I(D)/I(G) was calculated. Calculation results are shown in Table 1.

### 7. Evaluation of Semiconductor Component

With respect to the fabricated semiconductor component, the vicinity of the recess was observed under magnification with a scanning electron microscope. The amount of side etching was measured based on the observation results. The amount of the side etching is the maximum length from the opening of the recess to the end of the side etching.

Next, the amount of side etching was evaluated by comparing the measurement results with the following evaluation criteria. The measurement results and the evaluation results are shown in Table 1.
A: The amount of side etching is 5.0 μm or less
C: The amount of side etching is more than 5.0 μm

As is clear from the evaluation results shown in Table 1, it was found that the amount of side etching can be suppressed by using a silicon single crystal substrate on which a DLC film having I(D)/I(G) within a predetermined range is formed. From the above results, it was confirmed that a highly accurate etching process can be performed by using the semiconductor substrate according to the present disclosure.

What is claimed is:

1. A semiconductor substrate, comprising:
a first surface;
a second surface opposite the first surface; and
a diamond-like carbon film provided on the first surface of the substrate,
wherein an intensity of a D peak in a Raman spectrum of the diamond-like carbon film is defined as I(D), and an intensity of a G peak in the Raman spectrum is defined as I(G), and
a ratio of I(D)/I(G) satisfies I(D)/I(G)≤2.1.

2. The semiconductor substrate according to claim 1, wherein the diamond-like carbon film contains amorphous hydrogenated carbon.

3. The semiconductor substrate according to claim 1, wherein the intensity I(D) of the D peak and the intensity I(G) of the G peak satisfy 0.3≤I(D)/I(G).

4. The semiconductor substrate according to claim 1, wherein the intensity I(D) of the D peak and the intensity I(G) of the G peak satisfy I(D)/I(G)≤1.0.

5. The semiconductor substrate according to claim 1, wherein the diamond-like carbon film has a thickness of at least 25 nm.

6. The semiconductor substrate according to claim 1, wherein the diamond-like carbon film has a thickness of 120 nm or less.

7. The semiconductor substrate according to claim 1, further comprising an inorganic insulating film provided on the diamond-like carbon film.

8. The semiconductor substrate according to claim 7, wherein the inorganic insulating film is a silicon oxide film.

9. The semiconductor substrate according to claim 1, further comprising the diamond-like carbon film further provided on the second surface.

10. An etching method for etching the semiconductor substrate according to claim 1, the method comprising:
forming a resist film on the diamond-like carbon film so as to have an opening in a first region of the substrate and cover a second region of the substrate;
etching the diamond-like carbon film corresponding to the opening;
forming a porous noble metal film on a surface of the substrate corresponding to the first region; and
etching the substrate by bringing the noble metal film and the substrate into contact with an etching agent.

11. The etching method according to claim 10, wherein the semiconductor substrate further comprises an inorganic insulating film provided on the diamond-like carbon film,
wherein forming the resist film includes forming the resist film on the inorganic insulating film, and
etching the diamond-like carbon film includes removing the inorganic insulating film corresponding to the first region.

12. The etching method according to claim 10,
wherein etching the substrate includes forming a recess in the substrate by etching the substrate, and
when the depth of the recess is defined as d and the width of side etching generated in the recess is defined as w, the recess satisfies w/d≤0.02.

13. A method for manufacturing a semiconductor component, comprising performing an etching process on the semiconductor substrate by the etching method according to claim 10, thereby manufacturing the semiconductor component.
